(19) United States
(12) Patent Application Publication
(10) Pub. No.: US 2025/0039288 A1
(43) Pub. Date: Jan. 30, 2025

(54) FLEXIBLE DISPLAY TERMINAL

(71) Applicant: Ryu SANGKYU, Uiwang-Si (KR)

(72) Inventor: Ryu SANGKYU, Uiwang-Si (KR)

(21) Appl. No.: 18/713,913

(22) PCT Filed: Jan. 28, 2022
(86) PCT No.: PCT/KR2022/001599

§ 371 Date: May 28, 2024

(30) Foreign Application Priority Data
Jan. 28, 2021 (KR) 10-2021-0011969
Feb. 4, 2021 (KR) 10-2021-0015756
Jan. 6, 2022 (KR) 10-2022-0002378

(51) Int. Cl. H04M 1/02

(52) U.S. Cl. CPC H04M 1/0268

(57) ABSTRACT

The present invention has an automatic slide form to facilitate an extending/reducing operation of a flexible display portable terminal with only a simple operation. A slider method including a flexible display and various types of devices combined with same all have a flexible display accommodated while being bent, and, in this process, since an accommodation part is open, a foreign substance inflow prevention device and the like, which complement this open structure, is provided to prevent the inflow of dust and the like and incoming dust without direct friction against a screen unit of the flexible display. During the extension or reduction of a portable device including a flexible display, tensile force directly applied to the flexible display is minimized to minimize damage caused by the stress, and thus the device can be used for a long time.

### TECHNICAL FIELD

The present disclosure relates to a flexible display terminal with automatic and manual sliders.

Furthermore, the present disclosure relates to an automatic dust inflow prevention device for a flexible display terminal equipped with a flexible display and adopting a slider scheme.

Furthermore, the present disclosure relates to a flexible display terminal equipped with a flexible display stress prevention device for a portable device such as a folder type device, a slider type device, a wearable type device, a rollable device, and a roll-type device using a flexible display which is bendable, rollable, or foldable.

### BACKGROUND ART

Currently, a terminal using a flexible display in a form of a folder is manufactured and sold.

The demand from people seeking something more intuitive and convenient has also accelerated the development of a slide-type phone. However, the demand for automatic opening or closing or sliding is also increasing.

This demand is leading to emergence of a terminal that adopts various slider schemes according to the development of flexible display technology. The most simple form is adopting only a slider scheme. Furthermore, a combination of a slider scheme and a folder scheme is also being considered.

In addition, regarding a slider scheme, the emergence of a slide-out type device and a roll-type device is predicted.

Despite the emergence of these technologies, there are many concerns about the durability of the flexible display terminal operating in the folder scheme or the slider scheme.

### DISCLOSURE

### Technical Problem

A purpose of the present disclosure is to enable selective auto-slide, and enable expansion/reduction of a flexible display terminal with a simple manipulation.

The flexible display terminal may be expanded or reduced in various ways such as voice recognition, motion recognition, button manipulation, and manual manipulation. When an expand/reduction command is activated via voice recognition, motion recognition, knock, button manipulation, etc., movement of the slider and movement of the flexible display may be smoothly achieved using an auto-manual slider device.

In addition, in a terminal using only a slider scheme and having a flexible display and various types of devices including the same, the flexible display is partially bent so as to be accommodated in a housing. In this process, the housing is open. Thus, a foreign substance inflow prevention device supplements this open structure. The foreign substance inflow prevention device may prevent the inflow of dust and may remove the invading dust without direct friction on a screen of the flexible display.

Furthermore, a purpose of the present disclosure is intended to strengthen the durability against the stress of the flexible display which is widely used in a foldable manner, a slider manner, a rollable manner, or a wearable manner.

### Technical Solution

To this end, according to the present disclosure, a conveyor belt 101 engaged with an electric motor 100 as a power source operates, as shown in FIG. 1. In this regard, the conveyor belt 101 rotates around the electric motor 100 and a rotating roll 106.

A slider connector 103 is connected to a top of the conveyor belt. Thus, a slider slides when the conveyor belt rotates.

A flexible display connector 102 connected to a flexible display unit 105 is disposed at a bottom and moves from right to left on the drawing, such that the flexible display unit is pulled out along the rotating roll 106 as the slider is extended.

In this regard, the conveyor belt may be made of each of various materials such as fiber, rubber, and metal, and may have a form of a belt, a line, or an endless track.

However, when the motor device is in a form of a gear rather than a round form, the conveyor belt has teeth engaged with the gear of the motor.

In FIG. 1, the flexible display connector 102 is shown as being disposed only at an end. However, the flexible display connectors 102 may be arranged so as to be spaced from each other so as to be prevented from being spaced from the conveyor belt.

In one example, a hydraulic pump 200 may be used. When the hydraulic pump operates, the slider 104 and the slider connector 103 move in a forward direction, and the conveyor belt 101 rotates, and the flexible display unit 105 is extended along the rotating roll 106.

When using the hydraulic pump 200, the electric motor 100 may be replaced with the rotating roll 106 or the electric motor 100 and the rotating roll 106 may be used in parallel with each other.

When the automatic power device is excluded, an elastic device is disposed in the hydraulic pump 200 to manually operate the slider 104. The hydraulic pump 200 is also optional.

FIG. 3 shows sliding structures respectively disposed at both opposing sides.

Unlike FIG. 3, in the case of the slide-out scheme in which the slider extends left and right, the slider connector 103 is installed at the upper left and lower right or the upper right and lower left of the conveyor belt so that even when one conveyor belt rotates in one direction, the left and right sliders may extend or retract in different directions at the same time. A position of the connector at the top and bottom of the conveyor belt may be selected based on a sliding width. In the case of installing a plurality of conveyor belts with only one slider connector 103, the upper and lower positions may be arranged alternately.

The slider connector 102 adopts a hinge structure. After sliding by a certain length, the slider connector slides beyond a sliding guide of the housing, and thereafter an angle of the flexible display unit can be adjusted.

In addition, in case of placing one conveyor belt, a

folding function may be added by placing a hinge in the middle. In this regard, the conveyor belt which requires a length change according to folding may include a material such as rubber having elasticity.

In various types of devices with a flexible display to which the slider scheme is applied, the flexible display is partially bent so as to be accommodated in the housing. In this process, the housing is open. Thus, a foreign substance inflow prevention device supplements this open structure. The foreign substance inflow prevention device may prevent the inflow of dust and may remove the invading dust without direct friction on a screen of the flexible display.

In the process of extending and retracting the flexible display in the slider scheme, an flexible display inlet 1101 into the bent slider is introduced has an open structure, so that there is a problem of dust inflow into the housing through in the inlet 1101.

To solve this situation, flexible display inlet opening and closing means 1102 that may close and open the flexible display inlet is adopted. This opening and closing means 1102 may include a manual opening and closing means that may include a folder connected to the body housing 1100, a slider having a slider guide groove in the body housing 1100, and a button having a spring. Alternatively, the flexible display inlet opening and closing means 1102 may automatically operate using a device such as a gear via a connecting means such as a line, electricity, rod, etc. according to the association with the main body extension unit 1200.

For example, as shown in FIG. 8, an opening protrusion 1401 of the guide which is convex may be formed on the conveyor belt 1403 including the endless track operating according to the operation of the motor. When the conveyor belt or the like is rotated by the motor 1404 or manual force, the flexible display opening and closing means 1102 installed in the body housing 1100 is pushed upward according to the movement of the opening protrusion 1401 such that the flexible display inlet is automatically opened. The opening protrusion 1401 may extend in an elongate manner. Thus, the opening protrusion 1401 may continuously push upward the flexible display opening and closing means 1102 until the flexible display is fully extended. A closing groove 1402 may be formed at an end of the opening protrusion 1401 such that the flexible display opening and closing means 1102 is received in the groove 1402 when the flexible display is fully extended. In this regard, the opening protrusion 1401 may apply the pushing force toward the flexible display opening and closing means 1102. An elastic device 1405 such as a spring may be disposed between the flexible display opening and closing means 1102 and the housing such that the flexible display opening and closing means 1102 may be smoothly pushed upwards. Conversely, when the flexible display unit is extended and then retracted so as to be accommodated in the housing, the opening protrusion 1401 may continuously push upward the flexible display opening and closing means 1102 until the flexible display is fully retracted. When the flexible display is fully retracted, the flexible display opening and closing means 1102 slides down out of an end of the opening protrusion 1401 such that the flexible display opening and closing means 1102 closes the flexible display inlet.

Furthermore, this may be in conjunction with the foreign substance inflow prevention unit 1301.

In this regard, the flexible display opening and closing means 1102 may be made of a flexible material such as rubber or plastic to prevent damage to the flexible display screen 1300.

In addition, a body opening and closing means 1103 is defined at a lower end of the body housing 1100 so that dust introduced into the body housing may be manually removed through the body opening and closing means 1103. The user may manipulate the main body opening and closing means 1103 to manually remove the dust introduced into the device through the flexible display inlet. The body opening and closing means 1103 may also be connected to the main body and may operate in various schemes such as the folder scheme, the slider scheme, and the button scheme. Thus, when a large foreign substance such as sand invades the display device, the foreign substance may be removed without disassembling the device.

In another example, the foreign substance inflow prevention unit 1301 may be attached to an end of the flexible display screen, and may block the inflow of foreign substance or remove the foreign substance from the body housing. The foreign substance inflow prevention unit 1301 may act as a barrier so that the foreign substance stays only in a portion of the body housing, whereas the foreign substance may enter the housing when the flexible display inlet 1101 is open. However, when the main body extension unit 1200 is extended, the foreign substance inflow prevention part located at the end of the display screen moves up to a position of the flexible display inlet 1101 and blocks the inlet 1101.

The foreign substance inflow prevention unit 1301 may be interlocked with a locking device and may be engaged with an elastic device or a gear device.

The above three means may be used simultaneously or separately.

Furthermore, the present disclosure has introduced the dust inflow prevention unit for a slider phone with a flexible display extending to one side. Alternatively, the dust inflow prevention unit for a slider phone with a flexible display extending to both opposing sides also belongs to the scope of rights of the present disclosure.

In the process of bending or rolling the flexible display, the flexible display receives a lot of stress. As this bending or rolling process is repeated, the flexible display is damaged and thus, cannot exert its function.

This is because the flexible display unit directly receives the stress such as tensile force generated in the process of bending, rolling, or stretching the flexible display unit.

Therefore, a specific part of the flexible display or the housing may cope with the tensile force generated during the extending and retracting process of various types of portable devices such as foldable type, wearable type, slider type, and rollable type devices, so that only a relatively small amount of stress is transmitted to the flexible display to increase durability thereof. All the lines mentioned below may include materials such as fibers, carbon nanotubes, metals, and composite materials, and the forms of all the lines mentioned below may include all of connection forms such as lines, chains, and nodes.

In FIG. 9, a housing elastic connection line 2302 and a flexible display longitudinal line having a longitudinal line protrusion 2304 may be disposed in a flexible display lower end connection space 2103 formed at a lower end of the flexible display, and may continuously extend from a flexible display left end 2101 to a flexible display right end 2102, and may be connected to an elastic device of the portable device.

In addition, the flexible display longitudinal line 2303 extends from the left end 2101 of the flexible display to the right end 2102 of the flexible display through the connection space 2103 disposed at the lower end of the flexible display. In order to express the technology, the protrusion is shown as protruding vertically in FIG. 10. However, the protrusion may protrude horizontally along with the flexible display unit.

The connection space 2103 at the lower end of the flexible display is slightly larger than the flexible display longitudinal line protrusion 2304 accommodated therein. As the display of the portable device extends or retracts, a size of a left or right empty space in which the flexible display longitudinal line protrusion 2304 is absent in the connection space 210 may sequentially vary in a longitudinal direction.

The endless track 2200 is installed at the lower end or the side of the flexible display unit. In this regard, a flexible display fixing transverse line 2300 may be disposed on an upper end of the endless track 2200. A transverse spacing fixing line 2301 similar to the transverse fixing line 2300 may be present. A longitudinal line spacing protrusion 2304 is accommodated in the transverse spacing fixing line 2301. A fixing direction is oriented in a left-right direction as well as a vertical direction. In addition, the fixing device installed on the bottom or side of the housing of the portable device and the transverse spacing fixing line or the longitudinal spacing protrusion acts as a stopper so that the screen size may be adjusted in multiple stages in a detachable or retractable manner using a button or in an extended or retracted manner. he description of the multi-stage spacing adjustment fixing device is omitted because various technologies thereof have already been disclosed.

In the foldable terminal type, two or more spacing fixing lines 301 may be arranged by a small spacing in the two separated folder parts so as to be fixed during expansion, thereby minimizing the spacing between the housing and the flexible display unit that occurs when the two separated folder parts are expanded or retracted to provide a flat screen.

In this regard, when there is a sliding groove in the housing of the foldable terminal, a concave-convex display unit is disposed so that the sliding portion is disposed between two or more folder units or at the end of the folder, and a line or the like may be inserted into the concave-convex display lower end device. In the case of FIG. 13, the detailed configuration of the left end 2100 of the flexible display or the right end 2101 of the flexible display is further shown. Herein, there is a flexible display end connector 2104 connected to the flexible display longitudinal line and the housing elastic connection line 2302 to which the tensile force according to operations such as extending and retracting operations is directly transmitted. A second elastic device 2105 is built in the end connector of the flexible display, and is disposed in the left and right sides. The left and right sides 2100 and 2101 of the flexible display are connected to the elastic device 2105 so as to have slight movement. The device shown in FIG. 13 is optional, and the flexible display longitudinal lines 2302 and 2303 may be directly connected to the left and right sides 2101 and 2102 of the flexible display. All or some of the devices as shown herein may be employed.

In this way, the tensile force directly applied to the flexible display when the display unit of the flexible display terminal extends or retracts may be minimized to minimize the damage thereto caused by the stress so that the flexible display terminal may be used for a long time.

### Advantageous Effects

In accordance with the present disclosure, the hydraulic pump or the electric motor are connected to the conveyor belt to smoothly move the upper and lower sliders of the portable device with the flexible display while the durability is ensured.

Therefore, the display unit is configured to be able to extend or retract in various ways such as voice recognition, motion recognition, button manipulation, and manual work.

In addition, in a terminal using only a slider scheme and having a flexible display and various types of devices including the same, the flexible display is partially bent so as to be accommodated in a housing. In this process, the housing is Thus, open. foreign substance inflow a prevention device supplements this open structure. The foreign substance inflow prevention device may prevent the inflow of dust and may remove the invading dust without direct friction on a screen of the flexible display.

In the process of bending or rolling the flexible display, the flexible display receives a lot of stress. As this bending or rolling process is repeated, the flexible display is damaged and thus, cannot exert its function. Furthermore, a purpose of the present disclosure is intended to strengthen the durability against the stress of the flexible display which is widely used in a foldable manner, a slider manner, a rollable manner, or a wearable manner.

This is because the flexible display unit directly receives the stress such as tensile force generated in the process of bending, rolling, or stretching the flexible display unit.

Therefore, a specific part of the flexible display or the housing may cope with the tensile force generated during the extending and retracting process of various types of portable devices such as foldable type, wearable type, slider type, and rollable type devices, so that only a relatively small amount of stress is transmitted to the flexible display to increase durability thereof.

### DESCRIPTION OF DRAWINGS

FIG. 1 is a side structural diagram of a flexible display terminal.

FIG. 2 is an illustrative view of a flexible display terminal.

FIG. 3 is an illustrative view of a flexible display terminal having slider structures respectively at both opposing sides.

FIG. 4 is an illustrative view of a slider device having a flexible display.

FIG. 5 is an illustrative view of a form in which a flexible display is accommodated and a foreign substance inflow prevention unit 1301 attached to a flexible display terminal.

FIG. 6 is an illustrative view of a flexible display inlet opening and closing means 1102 and a body opening and closing means 1103 formed in a slider phone in which the flexible display is accommodated.

FIG. 7 is an illustrative view of a foreign substance inflow prevention unit 1301 after a screen unit 1300 of the flexible display terminal is fully extended.

FIG. 8 shows a screen unit 1300 of a flexible display terminal.

FIG. 9 is an illustrative view illustrating various devices installed on a lower end surface of the flexible display of the flexible display terminal.

FIG. 10 is an illustrative view showing a lower end connection space of a flexible display and a transverse line of the flexible display in a flexible display terminal.

FIG. 11 is an illustrative view having a flexible display slider device of a flexible display terminal.

FIG. 12 is an illustrative view of a rollable type device and a foldable type device among flexible display terminals.

FIG. 13 shows an end of a flexible display unit and a buffer elastic device formed at the end.

### BEST MODE

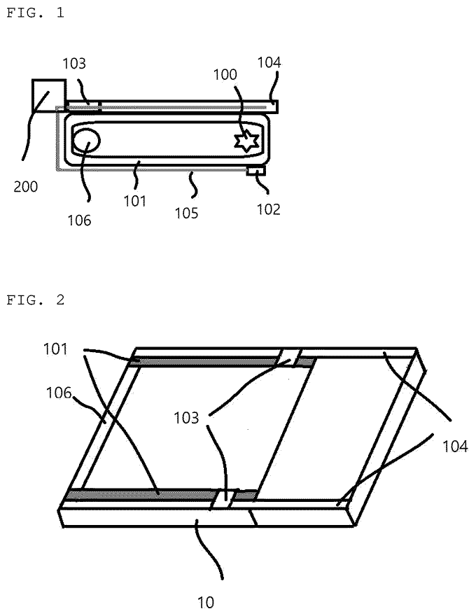

FIG. 1 is a side structural diagram of a flexible display terminal.

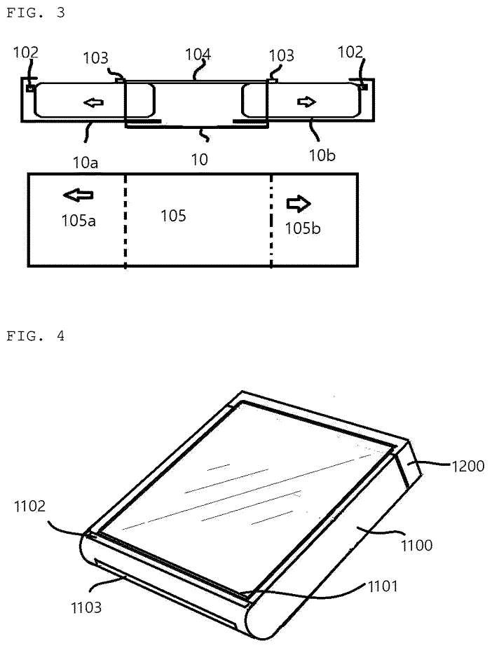

FIG. 2 is an illustrative view of a flexible display terminal.

FIG. 3 is an illustrative view of a flexible display terminal having slider structures respectively at both opposing sides.

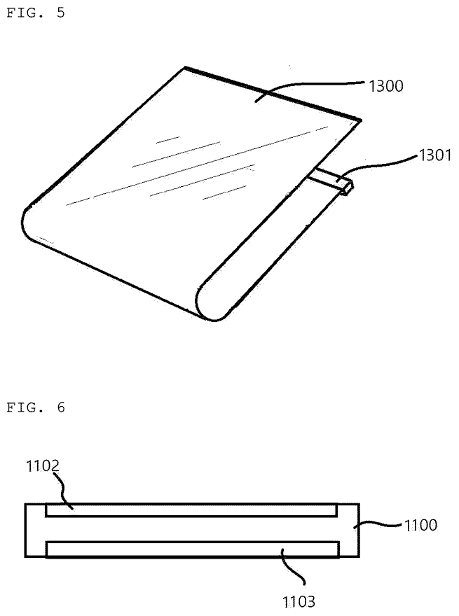

FIG. 4 is an illustrative view of a slider device having a flexible display.

FIG. 5 is an illustrative view of a form in which a flexible display is accommodated and a foreign substance inflow prevention unit 1301 attached to a flexible display terminal.

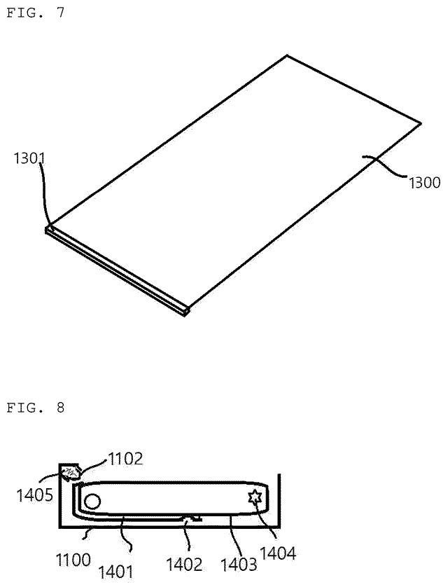

FIG. 6 is an illustrative view of a flexible display inlet opening and closing means 1102 and a body opening and closing means 1103 formed in a slider phone in which the flexible display is accommodated.

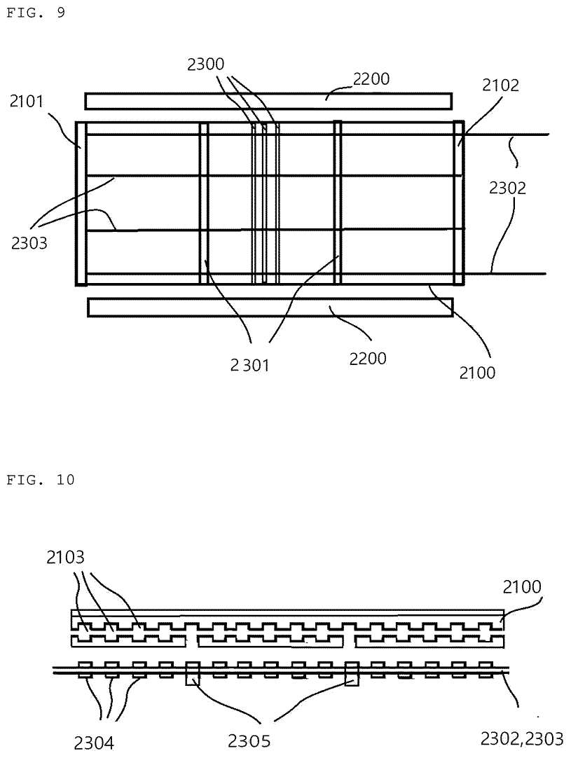

FIG. 7 is an illustrative view of a foreign substance inflow prevention unit 1301 after a screen unit 1300 of the flexible display terminal is fully extended. FIG. 8 shows a screen unit 1300 of a flexible display terminal.

FIG. 9 is an illustrative view illustrating various devices installed on a lower end surface of the flexible display of the flexible display terminal.

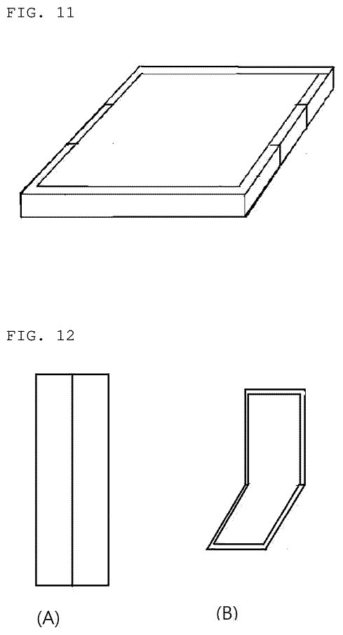

FIG. 10 is an illustrative view showing a lower end connection space of a flexible display and a transverse line of the flexible display in a flexible display terminal.

FIG. 11 is an illustrative view having a flexible display slider device of a flexible display terminal.

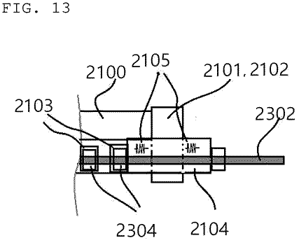

FIG. 12 is an illustrative view of a rollable type device and a foldable type device among flexible display terminals.

FIG. 13 shows an end of a flexible display unit and a buffer elastic device formed at the end.

### MODE

To this end, according to the present disclosure, a conveyor belt 101 engaged with an electric motor 100 as a power source operates, as shown in FIG. 1. In this regard, the conveyor belt 101 rotates around the electric motor 100 and a rotating roll 106.

A slider connector 103 is connected to a top of the conveyor belt. Thus, a slider slides when the conveyor belt rotates.

A flexible display connector 102 connected to a flexible display unit 105 is disposed at a bottom and moves from right to left on the drawing, such that the flexible display unit is pulled out along the rotating roll 106 as the slider is extended.

In this regard, the conveyor belt may be made of each of various materials such as fiber, rubber, and metal, and may have a form of a belt, a line, or an endless track.

However, when the motor device is in a form of a gear rather than a round form, the conveyor belt has teeth engaged with the gear of the motor.

In FIG. 1, the flexible display connector 102 is shown as being disposed only at an end. However, the flexible display connectors 102 may be arranged so as to be spaced from each other so as to be prevented from being spaced from the conveyor belt.

In one example, a hydraulic pump 200 may be used. When the hydraulic pump operates, the slider 104 and the slider connector 103 move in a forward direction, and the conveyor belt 101 rotates, and the flexible display unit 105 is extended along the rotating roll 106.

When using the hydraulic pump 200, the electric motor 100 may be replaced with the rotating roll 106 or the electric motor 100 and the rotating roll 106 may be used in parallel with each other.

When the automatic power device is excluded, an elastic device is disposed in the hydraulic pump 200 to manually operate the slider 104. The hydraulic pump 200 is also optional.

FIG. 3 shows sliding structures respectively disposed at both opposing sides.

Unlike FIG. 3, in the case of the slide-out scheme in which the slider extends left and right, the slider connector 103 is installed at the upper left and lower right or the upper right and lower left of the conveyor belt so that even when one conveyor belt rotates in one direction, the left and right sliders may extend or retract in different directions at the same time. A position of the connector at the top and bottom of the conveyor belt may be selected based on a sliding width. In the case of installing a plurality of conveyor belts with only one slider connector 103, the upper and lower positions may be arranged alternately.

The slider connector 102 adopts a hinge structure. After sliding by a certain length, the slider connector slides beyond a sliding guide of the housing, and thereafter an angle of the flexible display unit can be adjusted.

When placing the upper and lower slider coupling part on the conveyor belt, a separate conveyor belt connected only to the flexible display unit should be placed separately. Thus, as shown in FIG. 3, the entire position of the conveyor belt along the slider should be moved according to the screen expansion. One end of the flexible display unit may be fixed to the end of the slider and the other end thereof may be fixed to the conveyor belt. In another example, the existing scheme may be employed in which one end of the display unit is connected to the elastic device regardless of the conveyor belt.

In addition, in case of placing one conveyor belt, a folding function may be added by placing a hinge in the middle. In this regard, the conveyor belt which requires a length change according to folding may include a material such as rubber having elasticity.

In various types of devices with a flexible display to which the slider scheme is applied, the flexible display is partially bent so as to be accommodated in the housing. In this process, the housing is open. Thus, a foreign substance inflow prevention device supplements this open structure. The foreign substance inflow prevention device may prevent the inflow of dust and may remove the invading dust without direct friction on a screen of the flexible display.

In the process of extending and retracting the flexible display in the slider scheme, an flexible display inlet 1101 into the bent slider is introduced has an open structure, so that there is a problem of dust inflow into the housing through in the inlet 1101.

To solve this situation, flexible display inlet opening and closing means 1102 that may close and open the flexible display inlet is adopted. This opening and closing means 1102 may include a manual opening and closing means that may include a folder connected to the body housing 1100, a slider having a slider guide groove in the body housing 1100, and a button having a spring. Alternatively, the flexible display inlet opening and closing means 1102 may automatically operate using a device such as a gear via a connecting means such as a line, electricity, rod, etc. according to the association with the main body extension unit 1200.

For example, as shown in FIG. 8, an opening protrusion 1401 of the guide which is convex may be formed on the conveyor belt 1403 including the endless track operating according to the operation of the motor. When the conveyor belt or the like is rotated by the motor 1404 or manual force, the flexible display opening and closing means 1102 installed in the body housing 1100 is pushed upward according to the movement of the opening protrusion 1401 such that the flexible display inlet is automatically opened. The opening protrusion 1401 may extend in an elongate manner. Thus, the opening protrusion 1401 may continuously push upward the flexible display opening and closing means 1102 until the flexible display is fully extended. A closing groove 1402 may be formed at an end of the opening protrusion 1401 such that the flexible display opening and closing means 1102 is received in the groove 1402 when the flexible display is fully extended. In this regard, the opening protrusion 1401 may apply the pushing force toward the flexible display opening and closing means 1102. An elastic device 1405 such as a spring may be disposed between the flexible display opening and closing means 1102 and the housing such that the flexible display opening and closing means 1102 may be smoothly pushed upwards. Conversely, when the flexible display unit is extended and then retracted so as to be accommodated in the housing, the opening protrusion 1401 may continuously push upward the flexible display opening and closing means 1102 until the flexible display is fully retracted. When the flexible display is fully retracted, the flexible display opening and closing means 1102 slides down out of an end of the opening protrusion 1401 such that the flexible display opening and closing means 1102 closes the flexible display inlet.

Furthermore, this may be in conjunction with the foreign substance inflow prevention unit 1301.

In this regard, the flexible display opening and closing means 1102 may be made of a flexible material such as rubber or plastic to prevent damage to the flexible display screen 1300.

In addition, a body opening and closing means 1103 is defined at a lower end of the body housing 1100 so that dust introduced into the body housing may be manually removed through the body opening and closing means 1103. The user may manipulate the main body opening and closing means 1103 to manually remove the dust introduced into the device through the flexible display inlet. The body opening and closing means 1103 may also be connected to the main body and may operate in various schemes such as the folder scheme, the slider scheme, and the button scheme. Thus, when a large foreign substance such as sand invades the display device, the foreign substance may be removed without disassembling the device.

In another example, the foreign substance inflow prevention unit 1301 may be attached to an end of the flexible display screen, and may block the inflow of foreign substance or remove the foreign substance from the body housing. The foreign substance inflow prevention unit 1301 may act as a barrier so that the foreign substance stays only in a portion of the body housing, whereas the foreign substance may enter the housing when the flexible display inlet 1101 is open. However, when the main body extension unit 1200 is extended, the foreign substance inflow prevention part located at the end of the display screen moves up to a position of the flexible display inlet 1101 and blocks the inlet 1101.

The foreign substance inflow prevention unit 1301 may be interlocked with a locking device and may be engaged with an elastic device or a gear device.

The above three means may be used simultaneously or separately.

Furthermore, the present disclosure has introduced the dust inflow prevention unit for a slider phone with a flexible display extending to one side. Alternatively, the dust inflow prevention unit for a slider phone with a flexible display extending to both opposing sides also belongs to the scope of rights of the present disclosure.

In the process of bending or rolling the flexible display, the flexible display receives a lot of stress. As this bending or rolling process is repeated, the flexible display is damaged and thus, cannot exert its function.

This is because the flexible display unit directly receives the stress such as tensile force generated in the process of bending, rolling, or stretching the flexible display unit.

Therefore, a specific part of the flexible display or the housing may cope with the tensile force generated during the extending and retracting process of various types of portable devices such as foldable type, wearable type, slider type, and rollable type devices, so that only a relatively small amount of stress is transmitted to the flexible display to increase durability thereof. All the lines mentioned below may include materials such as fibers, carbon nanotubes, metals, and composite materials, and the forms of all the lines mentioned below may include all of connection forms such as lines, chains, and nodes.

In FIG. 9, a housing elastic connection line 2302 and a flexible display longitudinal line having a longitudinal line protrusion 2304 may be disposed in a flexible display lower end connection space 2103 formed at a lower end of the flexible display, and may continuously extend from a flexible display left end 2101 to a flexible display right end 2102, and may be connected to an elastic device of the portable device.

In addition, the flexible display longitudinal line 2303 extends from the left end 2101 of the flexible display to the right end 2102 of the flexible display through the connection space 2103 disposed at the lower end of the flexible display. In order to express the technology, the protrusion is shown as protruding vertically in FIG. 10. However, the protrusion may protrude horizontally along with the flexible display unit.

The connection space 2103 at the lower end of the

flexible display is slightly larger than the flexible display longitudinal line protrusion 2304 accommodated therein. As the display of the portable device extends or retracts, a size of a left or right empty space in which the flexible display longitudinal line protrusion 2304 is absent in the connection space 210 may sequentially vary in a longitudinal direction.

The endless track 2200 is installed at the lower end or the side of the flexible display unit. In this regard, a flexible display fixing transverse line 2300 may be disposed on an upper end of the endless track 2200. A transverse spacing fixing line 2301 similar to the transverse fixing line 2300 may be present. A longitudinal line spacing protrusion 2304 is accommodated in the transverse spacing fixing line 2301. A fixing direction is oriented in a left-right direction as well as a vertical direction. In addition, the fixing device installed on the bottom or side of the housing of the portable device and the transverse spacing fixing line or the longitudinal spacing protrusion acts as a stopper so that the screen size may be adjusted in multiple stages in a detachable or retractable manner using a button or in an extended or retracted manner. he description of the multi-stage spacing adjustment fixing device is omitted because various technologies thereof have already been disclosed.

In the foldable terminal type, two or more spacing fixing lines 301 may be arranged by a small spacing in the two separated folder parts so as to be fixed during expansion, thereby minimizing the spacing between the housing and the flexible display unit that occurs when the two separated folder parts are expanded or retracted to provide a flat screen.

In this regard, when there is a sliding groove in the housing of the foldable terminal, a concave-convex display unit is disposed so that the sliding portion is disposed between two or more folder units or at the end of the folder, and a line or the like may be inserted into the concave-convex display lower end device.

In the case of FIG. 13, the detailed configuration of the left end 2100 of the flexible display or the right end 2101 of the flexible display is further shown. Herein, there is a flexible display end connector 2104 connected to the flexible display longitudinal line and the housing elastic connection line 2302 to which the tensile force according to operations such as extending and retracting operations is directly transmitted. A second elastic device 2105 is built in the end connector of the flexible display, and is disposed in the left and right sides. The left and right sides 2100 and 2101 of the flexible display are connected to the elastic device 2105 so as to have slight movement. The device shown in FIG. 13 is optional, and the flexible display longitudinal lines 2302 and 2303 may be directly connected to the left and right sides 2101 and 2102 of the flexible display. All or some of the devices as shown herein may be employed.

In this way, the tensile force directly applied to the flexible display when the display unit of the flexible display terminal extends or retracts may be minimized to minimize the damage thereto caused by the stress so that the flexible display terminal may be used for a long time.

### INDUSTRIAL APPLICABILITY

The invention according to the present disclosure may be used for manufacturing the flexible display terminal using the flexible display.

1. A flexible display terminal including an electric motor, and at least one automatic slider configured to expand a screen in association with a conveyor belt.

2. A flexible display terminal including a hydraulic pump, and at least one automatic slider configured to expand a screen in association with a conveyor belt.

3. A flexible display terminal including a slider device having an elastic device, wherein the slider device is configured to expand a screen in association with a conveyor belt in a manual mode.

4. A flexible display terminal having an automatic dust inflow prevention device including a foreign substance inflow prevention unit configured to prevent inflow of a foreign substance, wherein the foreign substance inflow prevention unit is connected to at least one end of a flexible display unit.

5. A flexible display terminal having a stress prevention device extending in one or more lines from one end to the other end of a flexible display unit.
